(19) United States
(12) Patent Application Publication
(10) Pub. No.: US 2002/0189854 A1
(43) Pub. Date: Dec. 19, 2002

(54) Design for long fatigue life in flexible circuits

(76) Inventor: William R. Crumly, Anaheim, CA (US)

Correspondence Address: CHRISTIE, PARKER & HALE, LLP, 350 WEST COLORADO BOULEVARD, SUITE 500, PASADENA, CA, 91105, US

(21) Appl. No.: 09/829,715

(22) Filed: Apr. 10, 2001

(51) Int. Cl. H05K 1/00

(52) U.S. Cl. 174/254; 174/258; 29/830

(57) ABSTRACT

A multiple layer flexible circuit possessing a longer fatigue life. The flexible circuit includes one or more high modulus patches that force its traces into compression during flexion. The moduli of these patches are determined based on the materials used in the construction of the flexible circuit. Lower moduli materials can be used in the construction of the conductive layers to decrease the required moduli of the high modulus patches. One embodiment configured to be bent around an imaginary bending axis uses high modulus patches to force the neutral plane of the flexible circuit into the outermost surface the layer of traces furthest from the bending axis. This configuration maximizes the fatigue life of the circuit.

### FIELD OF THE INVENTION

The present invention relates generally to flexible circuits and, more particularly, to flexible circuits with increased fatigue lives.

### BACKGROUND OF THE INVENTION

Flexible circuits are used in a variety of applications. The thickness of flexible circuits and their ability to flex or conform to a confined space makes them suitable for interconnecting electrical components in situations where the inability of rigid boards to bend renders them inappropriate.

Flexible circuits are circuits formed on flexible dielectric substrates. These circuits can have one or more internal conductive layers as well as circuitry on one or both of the major surfaces of the circuit. The circuits often include additional layers such as insulating layers, adhesive layers, encapsulating layers or stiffening layers.

Different categories of flexible circuits can be identified based on the application for which the flexible circuit is designed. Static flexible circuits are designed so that they conform to a particular shape at the time of installation. Dynamic flexible circuits are designed to accommodate repeated flexing throughout the life of the circuit.

The repeated flexing of dynamic flexible circuits places strain on the layers of material used to construct the circuit. This strain can cause fine circuit traces to crack, which results in the failure of the circuit. The neutral plane is an imaginary plane generally parallel to the layers of material used to construct the flexible circuit. The location of the neutral plane defines which materials in the circuit experience compressive bending forces and which materials experience tensile bending forces. When a circuit is bent or flexed around an imaginary axis, the materials in the circuit that are on the side of the neutral plane closest to the bending axis experience compressive forces. The materials in the circuit that are on the side of the neutral plane remote from the bending axis experience tensile bending forces. Materials that are located exactly on the neutral plane experience neither compressive nor tensile forces during bending. The magnitude of the compressive or tensile forces experienced by materials in the circuit increase in relation to the distance of the material from the neutral plane. Ensuring that the circuit traces of a dynamic flexible circuit are on its neutral plane during bending or are always subject to compressive forces rather than tensile forces can reduce the likelihood of the circuit traces cracking.

The most cost effective way of ensuring that the circuit traces of a flexible circuit lie in its neutral plane is to construct the flexible circuit as a single layer flexible circuit. However, some circuits such as high frequency circuits containing stripline or microstrip transmission lines cannot be constructed as a single layer flexible circuit. A number of methods for reducing the strain on circuit traces of multiple layer flexible circuits are known. U.S. Pat. No. 4,756,940 to Payne, et al., discloses the use of a cover laminate to increase the bending radius of the flexible circuit and to reduce the strain placed on its circuit traces. U.S. Pat. No. 5,262,590 to Lia discloses a method of folding single layer circuits to achieve multiple layer circuits. This method can be used to construct multiple layer circuits containing a single layer of circuit traces, where circuit traces are along the neutral plane or plane of the flexible circuit.

There is, therefore, a need for an improved method of constructing multiple layer flexible circuits that is capable of controlling the location of the neutral plane of the resulting circuit in order to increase the fatigue life of the circuit.

### SUMMARY OF THE INVENTION

In accordance with practice of the present invention, a flexible circuit is provided with increased fatigue life. The flexible circuit has a neutral plane and is configured to be bent about an imaginary bending axis. The flexible circuit including at least one dielectric layer and at least two electrically conductive layers, where the electrically conductive layers are separated by the dielectric layers. In addition, the flexible circuit also includes a patch on the side of said flexible circuit opposite from the imaginary bending axis. The patch is configured so that the neutral plane is located either inside the electrically conductive layer that is remote from the bending axis, or between the outer surface of that electrically conducting layer and the outer surface of the patch.

### BRIEF DESCRIPTION OF THE DRAWINGS

FIG. 1 is a semi-schematic cross-sectional view showing a flexible circuit including a low modulus ground plane and a high modulus patch;

FIGS. 2A-2C are semi-schematic cross-sectional views illustrating the location of the neutral plane of a flexible circuit, when different materials are used in its construction;

FIG. 3 is a flow diagram showing the consecutive fabrication steps used to construct a flexible circuit with its neutral plane in a predetermined location;

FIGS. 4A-4F are semi-schematic cross-sectional views showing a flexible circuit during stages in is construction;

FIGS. 5A-5C are semi-schematic cross-sectional views illustrating multiple layer flexible circuits with different neutral planes;

FIG. 6 is a semi-schematic cross-sectional view showing a multiple layer flexible circuit being bent;

FIG. 7 is a semi-schematic cross-sectional view showing a multiple layer flexible circuit possessing a high modulus patch that forces its neutral plane into its outermost layer of traces being bent;

FIG. 8 is a semi-schematic cross-sectional view showing a multiple layer flexible circuit possessing a high modulus patch that forces its neutral plane outside of its traces being bent;

FIG. 9 is a semi-schematic cross-sectional view showing a multiple layer flexible circuit that is bent in two locations; and

FIG. 10 is a semi-schematic cross-sectional view showing a multiple layer flexible circuit that possesses two high modulus patches that force its traces into compression, when it is bent in the two locations shown.

### DETAILED DESCRIPTION OF THE INVENTION

Although detailed exemplary embodiments of the flexible circuit provided in accordance with practice of the present invention are disclosed herein, other suitable structures for practicing the present invention may be employed as will be apparent to persons of ordinary skill in the art.

Consequently, specific structural and functional details disclosed herein are representative only; they merely describe exemplary embodiments of the invention.

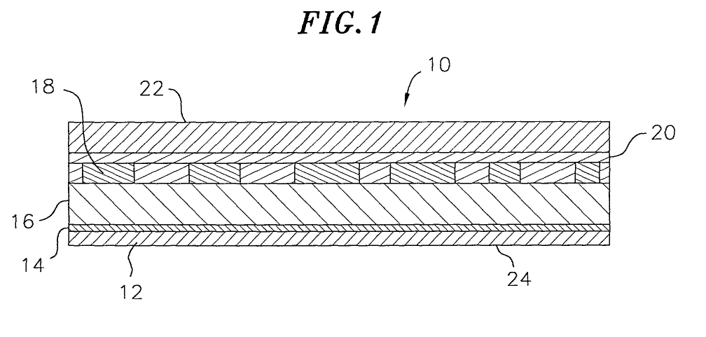

Turning to FIG. 1, one embodiment of a multiple layer flexible circuit 10 provided in accordance with practice of the present invention is shown. The flexible circuit includes a first coverlay 12, a low modulus layer of conductive material 14, a layer of flexible dielectric 16, a second layer of conductive material 18, a second coverlay 20 and a high modulus patch 22. The flexible circuit is particularly suited for the construction of high frequency flexible circuits containing microstrip transmission lines.

The layers of conductive material 14 and 18 contain the flexible circuit traces. The flexible dielectric layer 16 provides spacing between the conductive layers 14 and 18 and ensures that conduction between the conductive layers, signal losses and signal distortion are restricted to acceptable levels. The coverlays 12 and 20 protect the conductive layers from environmental damage. The high modulus patch 22 controls the location of the circuit neutral plane, which, in turn, is dependent upon the configuration and location of the components of the circuit and the characteristics of all of the materials used in its construction. When designing a circuit according to practice of the present invention, it is desirable to use materials with low moduli to minimize the modulus of the high modulus patch required to shift the neutral plane into a desired location. Increasing the modulus of the patch decreases the flexibility of the circuit, which is undesirable.

The choice of materials used in the construction of the conductive layers 14 and 18 and the flexible dielectric layer 16 is influenced by the nature of the signals carried by the traces in the conductive layers when the flexible circuit 10 is in operation. If a conductive layer carries high frequency signals or large currents, it can be constructed from a low resistivity material, such as a sheet of metal, to reduce signal losses and heat generation. Higher resistivity materials with low moduli such as conductive inks and conductive epoxies can be used, when the material can maintain acceptable signal losses and heat generation despite its higher resistivity. In one embodiment 10, the conductive layer 14 forms a ground plane and is constructed from a 0.0007 inch thick layer of silver epoxy having a modulus of 100,000 psi such as a silver epoxy manufactured by E. I. DuPont Nemours and Company and designated 5504. The second conductive layer 18, which forms a circuit plane and is patterned to contain circuit traces, is constructed from 0.5 oz layer of copper, having a modulus of 16,000,000 psi and a thickness of 0.001 inch. In another embodiment the circuit plane can be constructed from nickel.

The material used to construct the flexible dielectric layer 16 is preferably chosen to prevent distortion of the electrical signals carried within the conductive layers 14 and 18. In one exemplary embodiment, the flexible dielectric layer of the flexible circuit 10 is constructed from a 0.002 inch layer of polyimide material with a dielectric constant of 3.2, a loss tangent of 0.003 and a modulus in the range of 600,000 to 800,000 psi such as the IPC-FC-231/1 certified material identified as KAPTON E manufactured by the DuPont High Performance Films division of E. I. DuPont de Nemours and Company. The second conductive layer 18 is joined to the dielectric layer by a 0.0003 inch layer of adhesive with a modulus of 100,000 such as a PYROLUX adhesive manufactured the DuPont Flexible Circuit Group of E. I. DuPont de Nemours and Company.

In alternative embodiments, distortion can be prevented by constructing the flexible dielectric layer 16 from any material that has a dielectric constant which does not substantially vary with temperature, humidity or signal frequency, has a low loss tangent and has a low modulus. Alternative embodiments of the flexible circuit of the present invention incorporate a dielectric layer comprising a polyester, polyethylene naphthalate, polyetherimide or polytetrafluroethylene or the like.

The coverlays 12 and 20 are typically constructed to be as thin as possible subject to the constraint that they protect the layers of conductive material 14 and 18 from damage. In one exemplary embodiment, the coverlays 12 and 20 comprise a 0.0005 inch layer of polyimide with a modulus of 370,000 psi such as KAPTON manufactured by E. I. DuPont de Nemours and Company. In addition, the coverlays 12 and 20 are joined to the flexible circuit using 0.0005 inch of an adhesive with a modulus of 100,000 such as the adhesive identified as PYRALUX manufactured by the DuPont Flexible Circuit Materials Group of E. I. DuPont de Nemours and Company. In alternative embodiments, the coverlays can be constructed using other dielectric materials and adhesives, screened solder masks, screened dielectrics or liquid solder masks.

In accordance with practice of the present invention, a high modulus patch 22 is provided to move the location of the neutral plane of the flexible circuit 10 to a position that reduces the likelihood that the circuit traces contained within the layers of conductive material will crack. High modulus means having a modulus of at least 300,000 psi and preferably in excess of 1,000,000 psi. In one embodiment of the flexible circuit of the present invention, the high modulus patch 22 is constructed from a 0.002 inch thick layer of a polyimide material, which has a modulus of 1,280,000 psi such as a polyimide identified as UPILEX and manufactured by UBE INDUSTRIES, LTD. The patch is joined to the circuit by a 0.001 inch thick layer of adhesive with a modulus of 100,000 such as a PYRALUX adhesive. In the present embodiment, the patch 22 is configured and located to shift the flexible circuit neutral plane into the same plane as the second conductive layer 18 to thereby reduce the strain placed on the traces contained within the layer 18 during bending. In other embodiments of the patch 22, materials with higher or lower moduli can be used so long as the neutral plane is moved to its desired location within the circuit. The modulus of the high modulus patch 22 is less in embodiments where low modulus materials are used in the construction of the other elements of the circuit. It is desirable for the patch 22 to have a low modulus because the circuit 10 looses flexibility when the modulus of the patch is increased. In other embodiments of the flexible circuit, the functions of the patch 22 and the coverlay 20 can be served by a single layer of material.

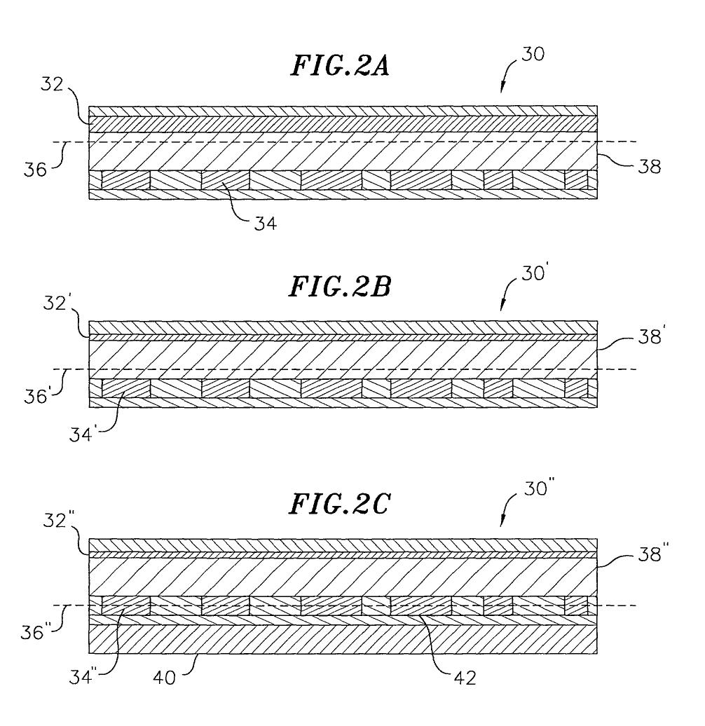

Turning now to FIGS. 2A-2C, the relationship between the neutral plane and the forces experienced by the traces of a two layer flexible circuit can be understood. Referring first to FIG. 2A, a double layer flexible circuit 30 comprising a high modulus ground plane 32 and a patterned layer of circuit traces 34 is shown. The flexible circuit 30 is similar to the flexible circuit 10 of FIG. 1, except that the flexible circuit 30 does not possess a high modulus patch and the ground plane 32 is constructed from a 0.5 oz copper foil. In this configuration, the neutral plane 36 of the circuit 30 passes through the dielectric layer 38 between the two conductive layers 32 and 34 and is generally parallel to the planes of the conductive layers. When the circuit is bent about an imaginary bending axis on the side of the circuit nearest the ground plane 32, the circuit traces 34 experience tensile forces.

Referring now to FIG. 2B in addition to FIG. 2A, a double layer flexible circuit 30′ that has a low modulus ground plane 32′ is illustrated. The flexible circuit 30′ is similar to the flexible circuit 10 of FIG. 1, except that the flexible circuit 30′ does not possess a high modulus patch. When the circuit is bent about an imaginary bending axis on the side of the circuit nearest the ground plane 321, the circuit traces 34′ experience tensile forces. Because of the use of the lower modulus material in the embodiment of FIG. 2B, the distance between the neutral plain 36′ and the plane of the traces 34′ is less than the distance between the neutral plane 36 and the plane of the traces 34 of the embodiment of FIG. 2A. The magnitude of the forces experienced during the bending described above increase with distance from the neutral plane. Therefore, the traces 34′ of the flexible circuit 30′ are subject to smaller tensile forces than those experienced by the traces 34 of the flexible circuit 30 during bending.

Referring now to FIG. 2C, one embodiment of a flexible circuit 30″ provided in accordance with practice of the present invention is shown. The flexible circuit 30″ is similar to the embodiment of the flexible circuit 10 of FIG. 1. A high modulus patch 40 is mounted on the trace side of the flexible circuit and has a thickness and modulus that forces the neutral plane 36″ into the same plane as the surface 42 of the circuit traces 34″ nearest the patch 40 or outer surface. When the circuit 30″ is bent about an imaginary bending axis on the side of the circuit nearest the ground plane 32″, the circuit traces 36″ do not experience tensile forces during bending and the compressive forces experienced by the traces 34″ are minimized. If the neutral plane were located beyond the surface 42 of the circuit traces 34″, the traces would not experience tensile forces during bending. However, the magnitude of the compressive forces on the circuit traces would be greater than when the neutral plane is along the outer surface 42 as shown because the traces would be further from the neutral plane.

The effect on circuit fatigue life of the location of the neutral plane is illustrated by the following examples. Experiments were performed on flexible circuits similar to the embodiments of FIGS. 2A-C to determine the fatigue life of each circuit.

### Example 1

A number of flexible circuits similar to the flexible circuit 30 of FIG. 2A were constructed. The flexible circuits were tested to determine their fatigue life, when they are bent around an imaginary axis located on the side of the circuit nearest the ground plane 32. The fatigue lives of the constructed circuits were measured experimentally by bending them with bend radius of curvature of 0.0002 in. The experimental results revealed that the average fatigue life of the circuits was 400 cycles. However, there was considerable variation in the results with one circuit failing after 1,600 cycles.

### Example 2

A number of flexible circuits similar to the flexible circuit 30′ of FIG. 2B were constructed. The flexible circuits were tested to determine their fatigue life, when they are bent around an imaginary axis located on the side of the circuit nearest the ground plane 32′ . The fatigue lives of the constructed circuits were measured experimentally by bending them with a bend radius of curvature of 0.0002 in. The experimental results indicated that the average fatigue life of the circuits was actually 28,000 cycles.

### Example 3

A number of flexible circuits similar to the flexible circuit 30″ of FIG. 2C were constructed. The flexible circuits were tested to determine their fatigue life, when they are bent around an imaginary axis located on the side of the circuit nearest the ground plane 32″. The fatigue lives of the constructed circuits were measured experimentally by bending them with a bend radius of curvature of 0.0002 in. The fatigue lives of the constructed circuits were measured experimentally by flexing them the circuit 30″ over a mandrel with a radius of curvature of 0.0002 in. Under experimental conditions, the circuits did not fail despite being tested beyond 3,000,000 cycles. Computer simulations indicated that the circuit fatigue life is in excess of 10,000,000 cycles.

The above examples show that flexible circuits with traces that are subjected to tensile forces during bending have fatigue lives significantly shorter than flexible circuits, such as those provided in accordance with practice of the present invention, which have traces that are subjected to compressive forces during bending. The magnitude and type of forces experienced by circuit traces of a flexible circuit are dependent upon the location of the circuit's neutral plane. Therefore, in order to provide flexible circuits in accorance with practice of the present invention incorporating a high modulus patch, one must be able to determine the location of the circuit neutral plane as a function of the characteristics and location of the patch. Thus, the modulus and thickness of high modulus patch required to establish the neutral plane of a flexible circuit in a specific location can be determined.

### Determination of the Location of the Neutral Plane

The location of the neutral plane of a stack consisting of layers of material with each layer having the same modulus, can be determined by adding the moduli of each of the layers and dividing this result by the sum of the cross sectional areas of each of the layers.

$$d = \frac{{M}_{Total}}{{A}_{Total}}$$

$${M}_{Total} = {\sum }_{i = 1}^{n} {M}_{i}$$

$${A}_{Total} = {\sum }_{i = 1}^{n} {A}_{i}$$

where d is the distance from the base of the stack to the neutral axis

M_{Total} is the moment of the stack

A_{Total} is the total cross sectional area of the stack

Mᵢ is the moment of layer i in the stack

Aᵢ is the cross sectional area of layer i in the stack

n is the total number of layers in the stack

A flexible circuit is not a stack of layers, where each layer has the same modulus. However, for the purposes of calculating the neutral plane location it is possible to model a flexible circuit as a stack of layers, where each layer has the same reference modulus. This can be done by modeling a layer of a given modulus E and width w as a layer possessing a reference modulus E_{ref} and having a width scaled according to the ratio E/E_{ref}. Therefore, each layer in the stack can be modeled as a layer having a moment and cross sectional area determined according to the following relationships:

$${M}_{i} = \frac{{b}_{i} ( {h}_{i}^{2} - {h}_{i - 1}^{2} )}{2}$$

$${A}_{i} = {t}_{i} {b}_{i}$$

$${b}_{i} = \frac{{w}_{i} {E}_{i}}{{E}_{ref}}$$

where bᵢ is the scaled width of layer i in the stack

hᵢ is the height of layer i relative to the base of the stack

tᵢ is the thickness of layer in the stack

wᵢ is the actual width of layer i in the stack

Eᵢ is the actual modulus of layer i in the stack

E_{ref} is the reference modulus

The distance of the neutral plane from the base of the stack can then be determined using the values for Mᵢ and Aᵢ developed according to the relationships defined above. Therefore, the modulus and thickness of a high modulus patch that establishes the neutral plane of a flexible circuit in a desired location can be determined by choosing a material of a given modulus to be used in the construction of the patch and then iteratively repeating the above calculations using different thicknesses of the patch, until the calculated position of the neutral plane corresponds to the desired location.

The following example shows the above predetermined method being used to calculate the location of the neutral plane for a flexible circuit provided in accordance with practice of the present invention having a configuration similar to the flexible circuit 10 of FIG. 1. A moment and a scaled cross sectional area are calculated for each of the layers: the first coverlay; the first coverlay adhesive layer; the low modulus conductive layer; the flexible dielectric layer; the dielectric adhesive; the high modulus conductive layer; the second coverlay adhesive layer; the second coverlay; the high modulus patch adhesive layer and the high modulus patch. Then, the neutral plane location is determined by dividing the total moment of the layers by their total cross sectional area. For this example, all distances are measured from the base of the circuit 24 and the reference modulus E_{ref} is chosen to be the modulus of the high modulus conductive layer which is 16,000,000 psi. Although it should be noted that any arbitrary modulus value can be chosen for E_{ref}. In addition, all of the layers have width w of 1.85 in.

### Definitions

E_{ref}=16×10⁶

w=1.85 in

### Calculations of Moment (M₁) and Cross Sectional Area (A₁) for First Coverlay

i=1

t=0.0005 in

E₁370,000 psi

$${b}_{1} = \frac{w {E}_{1}}{{E}_{ref}} = 0.043 in$$

A₁=t₁b₁=2.139×10⁻⁵ in²

h₁=t₁=5.0×10⁻⁴ in

$${M}_{1} = \frac{{( {b}_{1} ( {h}_{1} ) )}^{2}}{2} = 5.348 \times {10}^{- 9} {in}^{3}$$

### Calculations of Moment (M₂)and Cross Sectional Area (A₂)for the First Coverlay Adhesive Layer

i=2

t₂=0.0005 in

E₂=100,000 psi

$${b}_{2} = \frac{w {E}_{2}}{{E}_{ref}} = 0.012 in$$

A₂=t₂b₂=5.781×10⁻⁶ in²

h₂=h₁+t₂=1.0×10⁻³ in

$${M}_{2} = \frac{{b}_{2} ( {h}_{2}^{2} - {h}_{1}^{2} )}{2} = 4.336 \times {10}^{- 9} {in}^{3}$$

### Calculations of Moment (M₃)and Cross Sectional Area (A3)for the Low Modulus Conductive Layer

i=3

t₃=0.0007 in

E₃=100,000 psi

$${b}_{3} = \frac{w {E}_{3}}{{E}_{ref}} = 0.012 in$$

A₃=t₃b₃=8.094×10⁻⁶ in²

h₃h₂+t₃=1.7×10⁻³ in

$${M}_{3} = \frac{{b}_{3} ( {h}_{3}^{2} - {h}_{2}^{2} )}{2} = 1.093 \times {10}^{- 11} {in}^{3}$$

### Calculations of Moment (M₄)and Cross Sectional Area (A₄)for the Flexible Dielectric Layer

i=4

t₄=0.002 in

E₄=800,000 psi

$${b}_{4} = \frac{w {E}_{4}}{{E}_{ref}} = 0.092 in$$

A₄=t₄_{b}₄=1.85×10⁻⁴ in²

h₄=h₃+t₄=3.7×10⁻³ in

$${M}_{4} = \frac{{b}_{4} ( {h}_{4}^{2} - {h}_{3}^{2} )}{2} = 4.995 \times {10}^{- 7} {in}^{3}$$

### Calculations of Moment (M₅)and Cross Sectional Area (A₅)for the Dielectric Adhesive

i=5

t₅=0.0003 in

E₅=100,000 psi

$${b}_{5} = \frac{w {E}_{5}}{{E}_{ref}} = 0.012 in$$

A₅=t₅b₅=3.469×10⁻⁶ in²

h₅=h₄+t₅=4.0×10⁻³ in

$${M}_{5} = \frac{{b}_{5} ( {h}_{5}^{2} - {h}_{4}^{2} )}{2} = 1.335 \times {10}^{- 8} {in}^{3}$$

### Calculations of Moment (M₆)and Cross Sectional Area (A6)for the High Modulus Conductive Layer

Note—The high modulus conductive layer is not solid Cu, it is etched and the areas where Cu has been etched away are filled with adhesive. Therefore, the layer is modeled as being constructed half from Cu and half from dielectric adhesive (see formula for b₆ below)

i=6

t₆=0.001 in

E₆E_{ref}

$${b}_{6} = \frac{0.5 w {E}_{6}}{{E}_{ref}} + \frac{0.5 w {E}_{5}}{{E}_{ref}} = 0.931 in$$

A₆t₆b₆=9.308×10⁻⁴in²

h₆=h₅+t₆=5.0×10⁻³ in

$${M}_{6} = \frac{{b}_{6} ( {h}_{6}^{2} - {h}_{5}^{2} )}{2} = 4.189 \times {10}^{- 6} {in}^{3}$$

### Calculations of Moment (M₇)and Cross Sectional Area (A₇)for the Second Coverlay Adhesive Layer

i=7

t₇=0.0005 in

E₇=100,000 psi

E₇=100,000 psi

$${b}_{7} = \frac{w {E}_{7}}{{E}_{ref}} = 0.012 in$$

A₇=t₇b₇=5.781×10⁻⁶ in²

h₇=h₆+t₇=5.5×10⁻³ in

$${M}_{7} = \frac{{b}_{7} ( {h}_{7}^{2} - {h}_{6}^{2} )}{2} = 3.035 \times {10}^{- 8} {in}^{3}$$

### Calculations of Moment (M8)and Cross Sectional Area (A₈)for the Second Coverlay

i=8

t₈=0.0005 in

E₈=370,000 psi

$${b}_{8} = \frac{w {E}_{8}}{{E}_{ref}} = 0.043 in$$

A₈=t₈b₈2.139×10⁼⁵ in²

h₈ =h₇+t₈=6.0×10⁻³ in

$${M}_{8} = \frac{{b}_{8} ( {h}_{8}^{2} - {h}_{7}^{2} )}{2} = 1.23 \times {10}^{- 7} {in}^{3}$$

### Calculations of Moment (Mg)and Cross Sectional Area (Ag)for the High Modulus Patch Adhesive Layer

i=9

t₉=0.001 in

E₉=100,000 psi

$${b}_{9} = \frac{w {E}_{9}}{{E}_{ref}} = 0.012 in$$

A₉t₉b₉=1.156×10⁻⁵ in²

h₉=h₈+t₉=7.0×10⁻³ in

$${M}_{9} = \frac{{b}_{9} ( {h}_{9}^{2} - {h}_{8}^{2} )}{2} = 7.516 \times {10}^{- 8} {in}^{3}$$

### Calculations of Moment (M₁₀)and Cross Sectional Area (A₁₀)for the High Modulus Patch

i=10

t₁₀=0.002 in

E₁₀=1,280,000 psi

$${b}_{10} = \frac{w {E}_{10}}{{E}_{ref}} = 0.148 in$$

A₁₀t₁₀b₁₀=2.96×10⁻⁴ in²

h-hd 10h₉+t₁₀=9×10⁻³ in

$${M}_{10} = \frac{{b}_{10} ( {h}_{10}^{2} - {h}_{9}^{2} )}{2} = 2.368 \times {10}^{- 6} {in}^{3}$$

### Calculations of Total Moment (M_{Total}) of Stack and Total Cross Sectional area (A_{Total}) of Stack

$$\begin{matrix}{M}_{Total} = {\sum }_{i = 1}^{10} {M}_{i} \\ = ( \begin{matrix}5.348 \times {10}^{- 9} + 4.336 \times {10}^{- 9} + 1.093 \times {10}^{- 8} + \\ 4.995 \times {10}^{- 7} + 1.335 \times {10}^{- 8} + 4.189 \times {10}^{- 6} + \\ 3.035 \times {10}^{- 8} + 1.23 \times {10}^{- 7} + 7.516 \times {10}^{- 8} + 2.368 \times {10}^{- 6}\end{matrix} ) {in}^{3} \\ = 7.318 \times {10}^{- 6} {in}^{3}\end{matrix}$$

$$\begin{matrix}{A}_{Total} = {\sum }_{i = 1}^{10} {A}_{i} \\ = ( \begin{matrix}2.139 \times {10}^{- 5} + 5.781 \times {10}^{- 6} + 8.094 \times {10}^{- 6} + \\ 1.85 \times {10}^{- 4} + 3.469 \times {10}^{- 6} + 9.308 \times {10}^{- 4} + \\ 5.781 \times {10}^{- 6} + 2.139 \times {10}^{- 5} + 1.156 \times {10}^{- 5} + 2.96 \times {10}^{- 4}\end{matrix} ) {in}^{2} \\ = 1.489 \times {10}^{- 3} {in}^{2}\end{matrix}$$

### Calculation of Distance From Bottom of Stack to the Neutral Plane

$$\begin{matrix}d = \frac{{M}_{Total}}{{A}_{Total}} \\ = \frac{7.318 \times {10}^{- 6} {in}^{3}}{1.489 \times {10}^{- 3} {in}^{2}} \\ = 0.00491 in\end{matrix}$$

In the above example, the circuit traces 18 (ie the high modulus layer) occupy the space between 0.004 and 0.005 inches above the base 23 of the flexible circuit. The neutral plane lies 0.00491 inches above the base 14 and is therefore, just inside the surface of the circuit traces 18 proximate the high modulus patch. If the neutral plane is at the desired location, then no change is necessary. Conversely, if the neutral plane is not in the desired location, then additional iterations of the above calculations must be performed. In order to move the neutral plane closer to the outer surface of the high modulus patch, a greater value for the width of the high modulus patch is chosen and another iteration of the calculations performed. Alternatively, the neutral plane can be moved further from the outer surface of the high modulus patch by choosing a smaller value for the thickness of the high modulus patch. The above process is repeated, increasing or decreasing the thickness of the patch accordingly, until a value for the patch thickness is found that ensures that the neutral plane lies in the desired location.

In one preferred embodiment, the above process for determining the location of the neutral plane of a flexible circuit and for determining the width of high modulus patch required to shift the neutral plane to a desired location in accordance with practice of the present invention is performed by way of a computer program product which implements the inventive methods herein. Preferably the desired value of the thickness of the patch is determined using an iterative process such as the Newton-Raphson or similar method. In an alternative embodiment, dimensions and moduli of other layers in the design can be modified and the effect of these modifications on the width of high modulus patch required to establish the neutral plane in a desired location determined.

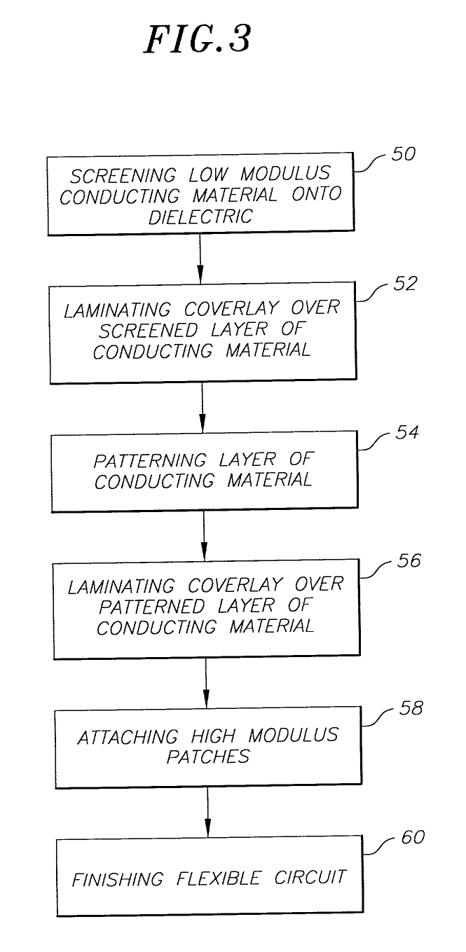

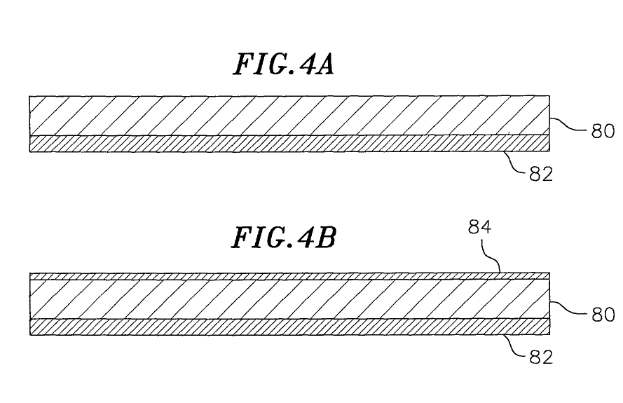

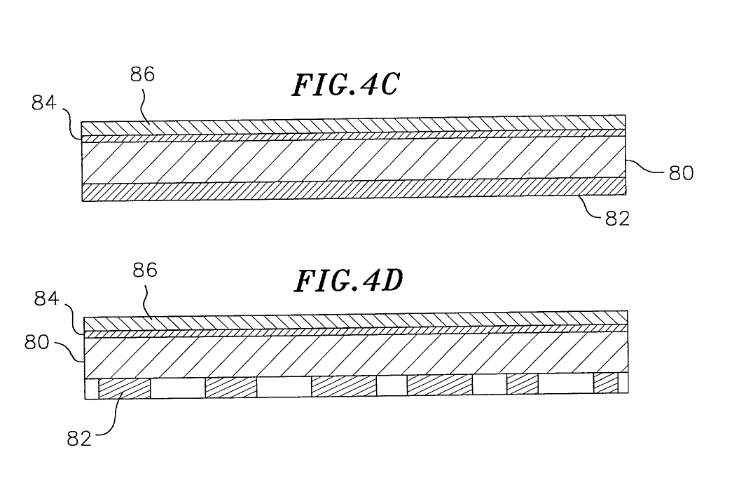

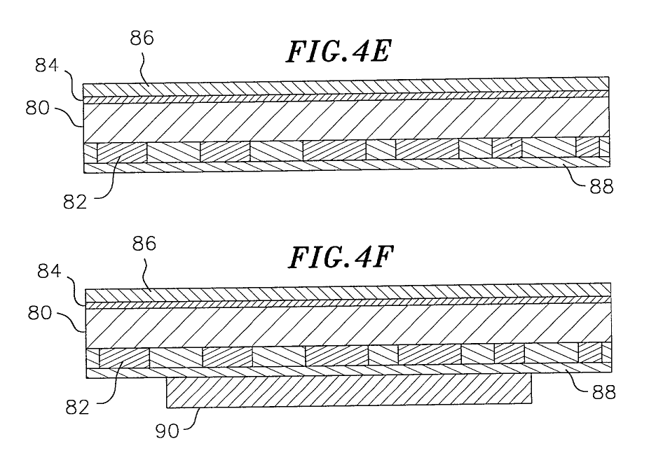

Turning now to FIGS. 3 and 4A-F, one exemplary series of process steps that can be used to fabricate a flexible circuit of the present invention is shown (FIG. 3) along with the structure at each stage of the process (FIGS. 4A-F) . Referring first to FIG. 4A, a layer of flexible dielectric material 80 pre-clad on one side with a sheet of conductive material 82 is illustrated. In other embodiments a sheet of conductive material can be laminated onto one side of a layer of flexible dielectric material or a layer of conductive material can be electrodeposited onto one side of the layer of flexible dielectric. U.S. Pat. No. 5,207,887 to Crumly et al. provides other examples of techniques that can be used to fix a conductor to the surface of a dielectric. U.S. Pat. No. 5,207,887 is incorporated by reference in its entirety into the present disclosure. The pre-clad dielectric is the structure that is operated on in the first steps of the fabrication process set forth in FIG. 3.

Referring to FIG. 4B, the first step 50 (FIG. 3) of screening low modulus conductive material 84 onto the unclad side of the layer of dielectric material 50 is illustrated. In one embodiment, the low modulus material is a silver epoxy conductive ink that is screened onto the flexible dielectric layer using silk screening. Other embodiments of the flexible circuit can be constructed using different low modulus conductive materials and screening techniques. Examples of the types of inks and the methods by which they can be fixed to the surface of a dielectric are described in U.S. Pat. No. 4,368,281 to Brummett et al. U.S. Pat. No. 4,368,281 is incorporated by reference in its entirety into the present disclosure.

Referring next to FIG. 4C, the step 52 (FIG. 3) of laminating a first coverlay 86 over the low modulus conductive material using lamination techniques well known in the lamination art 84 is illustrated. Referring to FIG. 4D, the next step 54 (FIG. 3) of patterning the conduction layer 82 is illustrated. In one embodiment the patterning can be done by etching. In alternative embodiments, the methods described in U.S. Pat. No. 4,368,281 to Crumly et al. above can also be used. Referring next to FIG. 4E, the step 56 (FIG. 3) of laminating a coverlay 88 over the patterned circuit traces 82 is shown.

Referring next to FIG. 4E, the step 58 (FIG. 3) of attaching a high modulus patch 90 to the circuit by lamination is illustrated. The patch 90 is constructed from material with a relatively high modulus and its location, thickness and modulus are chosen to reduce the likelihood that flexing the circuit will cause its traces to crack. Preferably, the patch is positioned on the circuit to ensure that the circuit neutral plane lies between the outside of the layer of circuit traces and the outside of the patch. After the patch has been attached, the flexible circuits are then finished in preparation for installation.

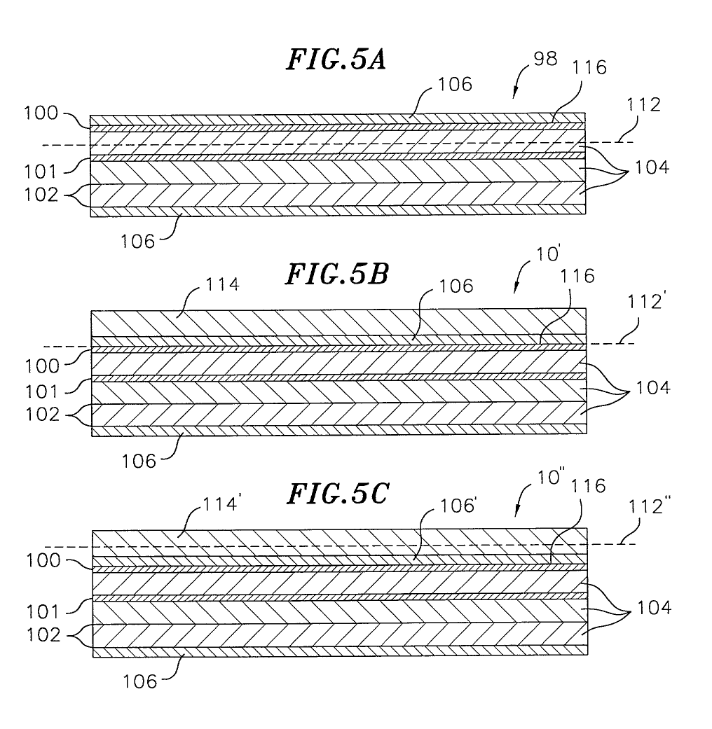

Turning now to FIG. 5A, a four layer flexible circuit 98 is illustrated which includes a pair of high modulus conductive layers 100 and 101 and a pair of low modulus conductive layers 102. The layers 100, 101 and 102 are separated from each other by flexible dielectric layers 104 and are protected from environmental damage by two coverlays 106. The materials that can be used to construct each layer of the multiple layer flexible circuit 98 are similar to the materials that can be used in the construction of the double layer flexible circuit 10 of the embodiment of FIG. 1. The neutral plane 112 of the flexible circuit 98 is located between the high modulus conductive layers 100.

Turning to FIG. 5B, one embodiment of a multiple layer flexible circuit 10′ provided in accordance with practice of the present invention is illustrated. The flexible circuit 10′ is formed by adding a modulus patch 114 on the side of the flexible circuit 98 of FIG. 5A, to provide that the circuit's neutral plane 112′ is moved from the location shown in FIG. 5A onto the outermost surface of the circuit trace 116. The dimensions of the patch 114 are chosen to span the width of the circuit 10′ and to cover the entire length of the portion of the circuit that is to be bent. The characteristics of the thickness and material of the high modulus patch 114 that are required to move the neutral plane from its position shown in FIG. 5A into the plane of the outermost surface of the circuit trace 116 (as shown in FIG. 5B) can be determined using the method described above.

Turning now to FIG. 5C in addition to FIG. 5A and FIG. 5B, another embodiment of a multiple layer flexible circuit 10″ provided in accordance with practice of the present invention with its neutral plane 112″ located outside its traces 100, 101 and 102 is illustrated. The circuit 10″ is identical to the circuit 10′ of FIG. 5B, except that the modulus of the high modulus patch 114′ is greater than the modulus of the high modulus patch 114.

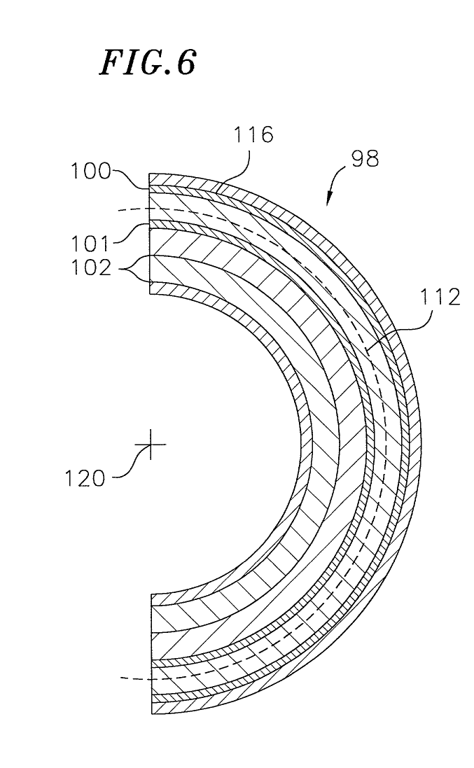

Turning now to FIGS. 6-8 in addition to FIGS. 5A-5C, each of the flexible circuits 98, 10′ and 10″ are shown being flexed or bent around an imaginary bending axis 120. Referring first to FIG. 6, the forces experienced by the flexible circuit 98 during bending can be understood. In the flexible circuit 98 the neutral plane 112 is located between the high modulus layers 100. When the circuit 98 is bent as shown, the conductive layer 100 furthest from the bending axis 120 experiences compressive forces, while the other conductive layers 101 and 102 experience tensile forces. Therefore, the circuit 98 has a high probably of failing under bending due to cracking of circuit traces in the conductive layer 100.

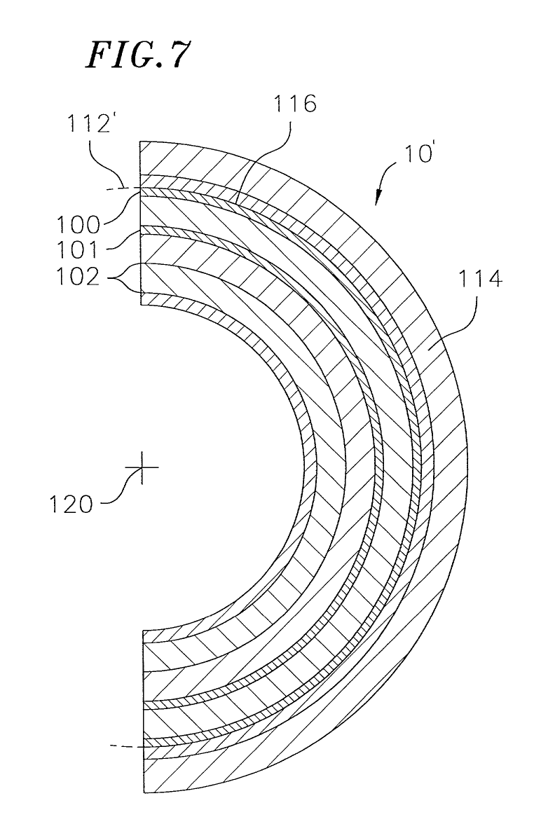

Referring now to FIG. 7 in addition to FIG. 6, the forces experienced by the flexible circuit 10′ constructed in accordance with practice of the present invention during bending around an imaginary bending axis 120 can be understood. Because the circuit neutral plane 112′ has been moved into the outermost surface of the circuit trace 116 by the high modulus patch 114, all of the traces 100 and 102 of the flexible circuit 10′ are under compression when the circuit is bent as shown. The likelihood that the traces within the flexible circuit 10′ will crack or fail is less than for the traces of the flexible circuit 98 of FIG. 6 because the traces of the circuit 101 only experience compressive forces during bending.

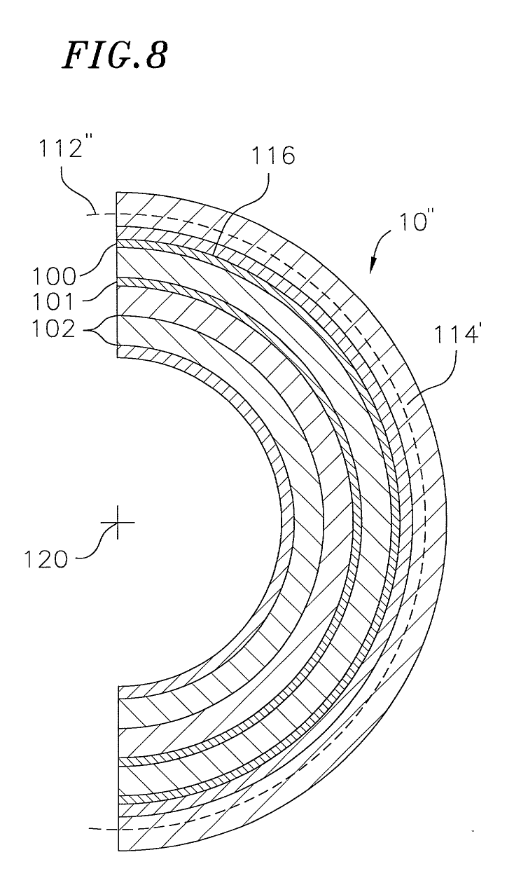

Referring to FIG. 8 in addition to FIG. 6 and FIG. 7, the forces experienced by the circuit traces of an embodiment of the present invention 10″ as it is bent around an imaginary bending axis 120 can be understood. When the flexible circuit 10″ is bent around the bending axis as shown, its traces 100 and 102 are all subject to compressive forces because the high modulus patch 114′ shifts the circuit neutral plane 112″ beyond the outermost surface of the circuit trace farthest from the bending axis 120. The compressive forces experienced by the traces 100 and 102 are greater than if the neutral plane 112″ were located at the outermost surface of the trace farthest from the bending axis 120 because the magnitude of forces experienced during bending increases with distance from the neutral plane. Despite this, the fatigue life of the circuit 10″ is considerably greater than it would be if any of the traces were subject to tensile forces.

Preferably, a flexible circuit constructed in accordance with the present invention will have a neutral plane located between the center of the conductive layer that is proximate the high modulus patch and the outside or outer surface of the high modulus patch. More preferably, the flexible circuit will have a neutral plane located between a point inside the conductive layer proximate the high modulus patch, a distance 10% of the width of the layer from the surface of the layer nearest the patch (ie the outer surface) and the outer surface of the patch. Most preferably, the flexible circuit will have a neutral plane located on the surface, which is nearest the high modulus patch, of the conductive layer proximate the patch.

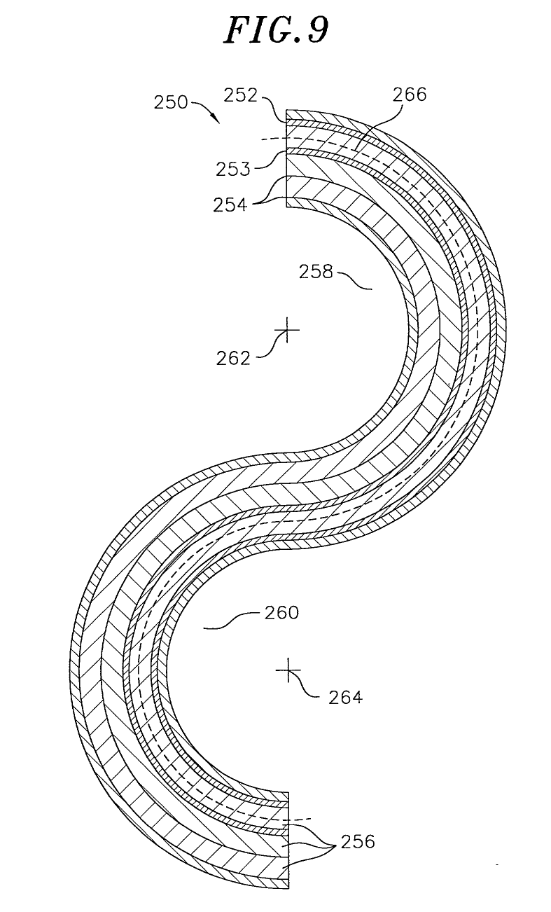

In alternative embodiments, multiple high modulus patches can be used to control the neutral plane of an installed flexible circuit so that its traces only experience compression forces. Turning now to FIG. 9, an installed four layer flexible circuit 250 comprising a pair of high modulus conductive layers 252 and 253 and a pair of low modulus conductive layers 254 separated by flexible dielectric layers 256 is bent in two places 258 and 260 around two bending axes 262 and 264 is illustrated. The neutral plane 266 of the circuit 250 is located such that the first bend 258 causes one of the high modulus conductive layers to experience tensile forces 252 and the second bend causes the other high modulus conductive layer 253 and the low modulus conductive layers 254 to experience tensile forces.

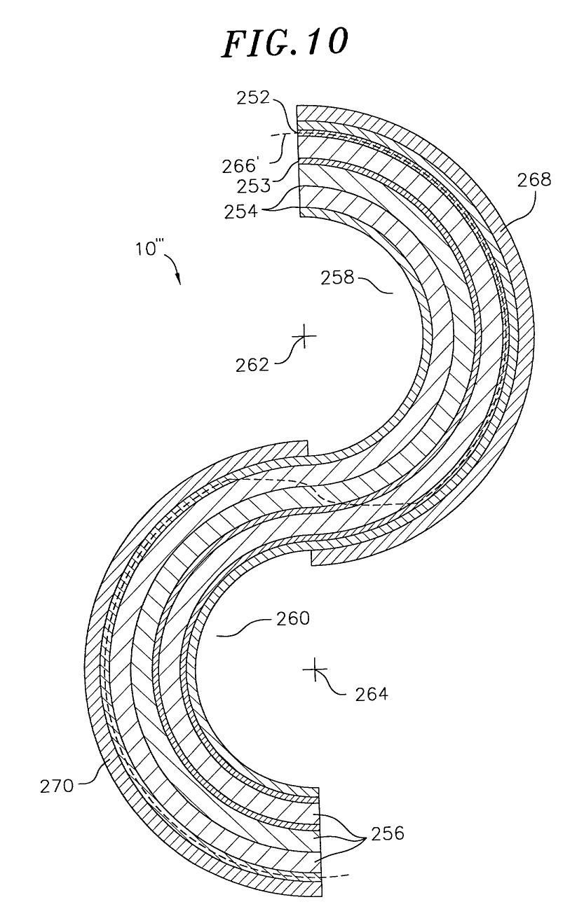

Turning now to FIG. 10, in addition to FIG. 9, another preferred embodiment of the present invention 10′″ which is similar to the flexible circuit 250 of FIG. 9 except for the incorporation of two high modulus patches 268 and 270 is illustrated. The high modulus patches 268 and 270 control the location of the circuit neutral plane 266′ so that its traces only experience compressive forces, when bent around the two imaginary bending axes 262 and 264. The characteristics of the patches can be determined using the iterative process described above. This embodiment 10′″ has a significantly greater fatigue life than the flexible circuit shown as 250 in FIG. 9 because the bends 258 and 260 only subject the conductive layers 252, 253 and 254 to compressive forces.

The embodiments illustrated as 10′, 10″ and 10′″ FIGS. 5, 5C and 10 contain two layers of low modulus conductive material and two layers of high modulus conductive material. However, the methods described above can be equally applied to the construction of any long fatigue life flexible circuit design, which contains two or more layers of conductive material. The embodiments illustrated above show the use of a single or two high modulus patches. However, the methods described above can be equally applied to use more than two high modulus patches to ensure that the circuit traces of a long fatigue life flexible circuit experience compressive forces when installed.

The above description of flexible circuits and the methods for forming such circuits are for illustration purposes. Because of variations which will be apparent to those skilled in the art, the present invention is not intended to be limited to the particular embodiments disclosed above. The scope of the invention is defined in the following claims.

What is claimed is:

1. A flexible circuit having a neutral plane and configured to be bent about an imaginary bending axis, said flexible circuit comprising:
at least one dielectric layer;
at least two electrically conductive layers, wherein said electrically conductive layers are separated by dielectric layers; and
a patch on the side of said flexible circuit opposite from the imaginary bending axis, said patch configured so that the neutral plane is located either inside the electrically conductive layer that is remote from the bending axis, or between the outer surface of said electrically conducting layer and the outer surface of said patch.

2. A flexible circuit having a neutral plane and configured to be bent about an imaginary bending axis, said flexible circuit comprising:
at least one dielectric layer;
at least two electrically conductive layers, wherein said electrically conductive layers are separated by dielectric layers; and
a patch on the side of said flexible circuit opposite from the imaginary bending axis, said patch configured so that the neutral plane is located between the outer surface of the patch and about the center of the electrically conductive layer that is remote from the bending axis.

3. The flexible circuit of claim 2, wherein said neutral plane is located between the outer surface of said patch and a location inside the electrically conductive layer that is remote from the bending axis, said location being a distance of about 10% of the thickness of the layer from its outer surface.

4. The flexible circuit of claim 2, wherein said neutral plane is located along the outer surface of the electrically conductive layer that is remote from said bending axis.

5. The flexible circuit of claim 2, wherein at least one of said electrically conductive layers comprises a plurality of circuit traces.

6. The flexible circuit of claim 5, wherein the electrically conductive layer remote from the bending axis comprises a plurality of circuit traces.

7. The flexible circuit of claim 2, wherein said dielectric layer comprises a polyimide.

8. The flexible circuit of claim 2, wherein at least one of said electrically conductive layers comprises copper.

9. The flexible circuit of claim 2, wherein at least one of said electrically conductive layers comprises nickel.

10. A flexible circuit having a neutral plane and configured to be bent about an imaginary bending axis, said flexible circuit comprising:
at least two electrically conductive layers;
at least one dielectric layer separating the electrically conductive layers;
at least one high modulus patch, wherein said patch is configured and located on the side of the flexible circuit that is remote from the bending axis to provide that said conductive layers are subjected to compressive forces during bending of said circuit about said bending axis.

11. A flexible circuit having a neutral plane and configured to be bent about an imaginary bending axis, said flexible circuit comprising:
at least two electrically conductive layers;
at least one dielectric layer separating the electrically conductive layers;
a high modulus patch, wherein said patch is configured such that the location of the neutral plane of the flexible circuit is further from the imaginary bending axis than the location of the neutral plane would be without said patch.

12. The flexible circuit of claim 11, wherein said dielectric layer comprises a polyimide.

13. The flexible circuit of claim 11, wherein one of said electrically conductive layers comprises copper.

14. A method of constructing a flexible circuit having a neutral plane, comprising the steps of:
a. choosing a first estimate of the thickness of the patch;
b. determining the total modulus of the flexible circuit and the patch;
c. determining the total cross sectional area of the flexible circuit and the patch;
d. determining the location of the neutral plane of said flexible circuit and patch combination using the total modulus and the total cross sectional area of the flexible circuit and the patch; and
e. providing the patch with said first estimated thickness when said location of the neutral plane falls within a range of desired locations; or
f. when said location of the neutral plane determined in step d. falls outside the range of desired locations, choosing a second estimate of the thickness of said patch as a function of the distance of said neutral plane from said desired location and repeating steps b. , c., d. and e. until the estimated patch thickness provides that the neutral plane is within the range of desired locations.

15. A method for determining the thickness of a patch of given modulus, which is to be attached on one side of a flexible circuit having a neutral plane and a base, the method comprising the steps of:
a. choosing a first estimate of the thickness of the patch;
b. determining the total modulus of the flexible circuit and the patch;
c. determining the total cross sectional area of the flexible circuit and the patch;
d. determining the location of neutral plane of said flexible circuit and patch combination relative to said base using the total modulus and the total cross sectional area of the flexible circuit and the patch; and
e. choosing said estimate as the thickness of said patch when said location of the neutral plane determined in step d. falls within a range of desired locations; or
f. when said location of the neutral plane determined in step d. falls outside the range of desired locations, choosing a second estimate of the thickness of said patch as a function of the distance of said neutral plane from said desired location and repeating steps b., c., d. and e. until the estimated patch thickness provides that the neutral plane is within the range of desired locations.

16. The method of claim 15, wherein:
said range of desired locations has an upper limit relative to said base and a lower limit relative to said base; and
said second estimate is chosen to be greater than said first estimate if the location of said neutral plane relative to said base is below said lower limit, else said second estimate is chosen to be less than said first estimate.

17. The method claim 15, wherein said second estimate is determined according to the Newton-Raphson method.

18. A method for determining the desired thickness of a patch of given modulus, which is to be added to one side of a flexible circuit having a neutral plane and a base, comprising:
a. choosing a first estimate of the thickness of the patch;
b. determining the total modulus M_{Total} of the flexible circuit and the patch using a first predetermined method;
c. determining the total cross sectional area A_{Total} of the flexible circuit and the patch using a second predetermined method;
d. determining the location of the neutral plane of said flexible circuit and patch combination relative to said base using the formula:
$$d = \frac{{M}_{Total}}{{A}_{Total}}$$
e. selecting said first estimate as the desired thickness of said patch when said location of the neutral plane determined in step d. relative to said base falls within a range of desired locations; or
f. when said location of the neutral plane determined in step d. falls outside the range of desired locations, choosing a new estimate for the thickness of said patch according to the distance of said location of neutral plane from said desired location and repeating b., c., d. and e. until the estimated patch thickness provides that the neutral plane is within the range of desired locations.

19. A method for determining the thickness of a patch of given modulus, which is to be added to one side of a flexible circuit having a neutral plane and a base and a plurality of layers, comprising:
a. choosing a first estimate of the thickness of the patch;
b. scaling the width of each of said layers by the ratio of the modulus of the layer to a reference modulus;
c. determining the total modulus M_{Total} of the flexible circuit and the patch using a first predetermined method;
d. determining the total cross sectional area A_{Total} of the flexible circuit and the patch using a second predetermined method;
e. determining the location of the neutral plane of said flexible circuit and patch combination relative to said base using the formula:
$$d = \frac{{M}_{Total}}{{A}_{Total}}$$
f. selecting said first estimate as the desired thickness of said patch when said location of the neutral plane determined in step e. relative to said base falls within a range of desired locations; or
g. when said location of the neutral plane determined in step e. falls outside the range of desired locations, choosing a new estimate for the thickness of said patch according to the distance of said location of neutral plane from said desired location and repeating b., c., d., e. and f. until the estimated patch thickness provides that the neutral plane is within the range of desired locations.
